(19) United States
(12) Patent Application Publication
(10) Pub. No.: US 2023/0223740 A1
(43) Pub. Date: Jul. 13, 2023

(54) SEMICONDUCTOR LASER ELEMENT

(71) Applicant: Panasonic Holdings Corporation, Osaka (JP)

(72) Inventor: Hiroyuki HAGINO, Osaka (JP)

(21) Appl. No.: 18/178,217

(22) Filed: Mar. 3, 2023

Related U.S. Application Data
(63) Continuation of application No. PCT/JP2021/025862, filed on Jul. 8, 2021.

(30) Foreign Application Priority Data
Sep. 30, 2020 (JP) 2020-166382

(51) Int. Cl. H01S 5/10; H01S 5/026

(52) U.S. Cl. CPC H01S 5/1039; H01S 5/026

(57) ABSTRACT

A semiconductor laser element is a semiconductor laser element that emits laser light, and the semiconductor laser element includes a substrate, a first semiconductor layer above the substrate, a light emitting layer above the first semiconductor layer, a second semiconductor layer above the light emitting layer, and a dielectric layer above the second semiconductor layer. The second semiconductor layer includes a waveguide that guides the laser light. A width of at least a portion of the waveguide is modulated with respect to a position in a direction of resonator length, the direction being a longitudinal direction of the waveguide. The waveguide includes a first waveguide and a second waveguide that is wider than the first waveguide. A difference between an effective index of refraction inside the waveguide and an effective index of refraction outside the waveguide is greater in the second waveguide than in the first waveguide.

### CROSS REFERENCE TO RELATED APPLICATIONS

This is a continuation application of PCT International Application No. PCT/JP2021/025862 filed on Jul. 8, 2021, designating the United States of America, which is based on and claims priority of Japanese Patent Application No. 2020-166382 filed on Sep. 30, 2020. The entire disclosures of the above-identified applications, including the specifications, drawings and claims are incorporated herein by reference in their entirety.

### FIELD

The present disclosure relates to a semiconductor laser element that includes a waveguide whose width is modulated with respect to the position in the direction of resonator length.

### BACKGROUND

In recent years, a semiconductor laser element is attracting attention for its use as a light source in various applications, and examples of such a light source include a light source of an image display device, such as a display or a projector; a light source of a headlamp of a vehicle; a light source of industrial lighting or consumer lighting; or a light source of industrial equipment, such as a laser welding apparatus, a thin film annealing apparatus, or a laser machining apparatus. Moreover, a semiconductor laser element used as a light source in any of the aforementioned applications is expected to have a high beam quality and a high output power far exceeding an optical output of one watt.

In order to achieve a high beam quality, a laser is desired to oscillate in the fundamental mode (i.e., in the fundamental transverse mode). In one technique for achieving an operation in the fundamental mode, the width of a waveguide in a laser is kept small, and the laser is operated in a state in which optically no higher order mode is present (in a cutoff state). However, a waveguide having a larger width (a wide stripe) is more advantageous in achieving a high output power, and thus the transverse mode of laser light of a high output power exceeding an optical output of one watt is often a higher order mode. In the following description, a higher order mode in the transverse direction is simply referred to also as a higher order mode.

Patent Literature 1 discloses conventional semiconductor laser element 1000. FIG. 6 is a top view of conventional semiconductor laser element 1000 disclosed in Patent Literature 1.

As illustrated in FIG. 6, conventional semiconductor laser element 1000 includes rough surface optical waveguide mechanism 1001 and parallel sliding surface waveguide mechanism 1002. Rough surface optical waveguide mechanism 1001 has a ragged shape and is provided at a center portion in a wave guiding direction of each side surface of a stripe-shaped ridge portion. Parallel sliding surface waveguide mechanism 1002 is provided at each end portion in the wave guiding direction. This rough surface optical waveguide mechanism 1001 causes loss of a higher order mode, and thus the proportion of the fundamental mode can be increased.

### CITATION LIST

### Patent Literature

PTL 1: Japanese Unexamined Patent Application Publication No. 9-246664

### SUMMARY

### Technical Problem

Despite the above, semiconductor laser element 1000 described in Patent Literature 1 may experience not only the loss of a higher order mode but also an increase in the loss of the fundamental mode. Therefore, as the ratio of the fundamental mode decreases, the beam quality may decrease.

The present disclosure is directed to providing a semiconductor laser element of a high beam quality.

### Solution to Problem

To solve the problem described above, one aspect of a semiconductor laser element according to the present disclosure is a semiconductor laser element that emits laser light, and the semiconductor laser element includes: a substrate; a first semiconductor layer above the substrate; a light emitting layer above the first semiconductor layer; a second semiconductor layer above the light emitting layer; and a dielectric layer above the second semiconductor layer, wherein the second semiconductor layer includes a waveguide that guides the laser light, a width of at least a portion of the waveguide is modulated with respect to a position in a direction of resonator length, the direction being a longitudinal direction of the waveguide, the waveguide includes a first waveguide and a second waveguide that is wider than the first waveguide, and a difference between an effective index of refraction inside the waveguide and an effective index of refraction outside the waveguide is greater at the second waveguide than at the first waveguide.

With this configuration, the loss of the fundamental mode of the laser light can be reduced in the first waveguide where the waveguide has a small width. Along with this effect, the proportion of the fundamental mode having a higher beam quality in the laser light that semiconductor laser element 1 emits can be increased, and thus semiconductor laser element 1 of a high beam quality can be achieved.

Moreover, in one aspect of the semiconductor laser element according to the present disclosure, an angle formed by a side surface intersecting with a widthwise direction of the waveguide and the direction of resonator length may be greater than a critical angle at the first waveguide and smaller than the critical angle at the second waveguide, and the critical angle may be defined by the effective index of refraction inside the waveguide and the effective index of refraction outside the waveguide.

This configuration makes it possible to keep the fundamental mode from being reflected in the first waveguide. Accordingly, a semiconductor laser element of a high beam quality can be achieved.

Moreover, in one aspect of the semiconductor laser element according to the present disclosure, the second semiconductor layer may be thicker outside the first waveguide than outside the second waveguide.

With this configuration, the difference between the effective index of refraction of the first waveguide and the effective index of refraction of the first planar portion can be made smaller than the difference between the effective index of refraction of the second waveguide and the effective index of refraction of the second planar portion.

Moreover, in one aspect of the semiconductor laser element according to the present disclosure, the dielectric layer may have a smaller index of refraction than the second semiconductor layer.

This configuration makes it possible to trap the laser light in the second semiconductor layer.

### Advantageous Effects

The present disclosure can provide a semiconductor laser element of a high beam quality.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1A is a schematic top view illustrating a configuration of a semiconductor laser element according to an embodiment.

FIG. 1B is a schematic first sectional view illustrating a configuration of a semiconductor laser element according to an embodiment.

FIG. 1C is a schematic second sectional view illustrating a configuration of a semiconductor laser element according to an embodiment.

FIG. 1D is a graph illustrating a result of calculating a relationship between the critical angle and the difference (ni−no) between the effective indexes of refraction inside and outside a waveguide according to an embodiment.

FIG. 2A is a schematic sectional view illustrating a first step of a method of manufacturing a semiconductor laser element according to an embodiment.

FIG. 2B is a schematic sectional view illustrating a second step of a method of manufacturing a semiconductor laser element according to an embodiment.

FIG. 2C is a schematic sectional view illustrating a third step of a method of manufacturing a semiconductor laser element according to an embodiment.

FIG. 2D is a schematic top view illustrating a third step of a method of manufacturing a semiconductor laser element according to an embodiment.

FIG. 2E is a schematic sectional view illustrating a fourth step of a method of manufacturing a semiconductor laser element according to an embodiment.

FIG. 2F is a schematic top view illustrating a fourth step of a method of manufacturing a semiconductor laser element according to an embodiment.

FIG. 2G is a schematic sectional view illustrating a fifth step of a method of manufacturing a semiconductor laser element according to an embodiment.

FIG. 2H is a schematic top view illustrating a fifth step of a method of manufacturing a semiconductor laser element according to an embodiment.

FIG. 2I is a schematic sectional view illustrating a sixth step of a method of manufacturing a semiconductor laser element according to an embodiment.

FIG. 2J is a schematic top view illustrating a sixth step of a method of manufacturing a semiconductor laser element according to an embodiment.

FIG. 2K is a schematic sectional view illustrating a seventh step of a method of manufacturing a semiconductor laser element according to an embodiment.

FIG. 2L is a schematic sectional view illustrating an eighth step of a method of manufacturing a semiconductor laser element according to an embodiment.

FIG. 2M is a schematic sectional view illustrating a ninth step of a method of manufacturing a semiconductor laser element according to an embodiment.

FIG. 2N is a schematic sectional view illustrating a tenth step of a method of manufacturing a semiconductor laser element according to an embodiment.

FIG. 3A is a schematic top view of a semiconductor laser device provided with a semiconductor laser element according to an embodiment.

FIG. 3B is a schematic sectional view of a semiconductor laser device provided with a semiconductor laser element according to an embodiment.

FIG. 4A is a top view illustrating, in a simplified manner, a configuration of a semiconductor laser element according to an embodiment.

FIG. 4B is a diagram illustrating a distribution of effective indexes of refraction in a semiconductor laser element observed along the IVB-IVB section indicated in FIG. 4A.

FIG. 4C is a diagram illustrating a distribution of effective indexes of refraction in a semiconductor laser element observed along the IVC-IVC section indicated in FIG. 4A.

FIG. 5A is a graph illustrating a result of calculating a relationship between the amount of change in Δn and the loss of light of the fundamental mode.

FIG. 5B is a graph illustrating a result of calculating a relationship between the amount of change in Δn and BPP.

FIG. 6 is a top view of a conventional semiconductor laser element disclosed in Patent Literature 1.

### DESCRIPTION OF EMBODIMENTS

Hereinafter, some embodiments of the present disclosure will be described with reference to the drawings. It is to be noted that the embodiments described below illustrate merely specific examples of the present disclosure. Therefore, the numerical values, the shapes, the materials, the constituent elements, the arrangement positions and the connection modes of the constituent elements, and so on illustrated according to the following embodiments are merely examples and are not intended to limit the present disclosure.

Moreover, the drawings are schematic diagrams and do not necessarily provide the exact depictions. Hence, the scales and so on do not necessarily match among the drawings. In the appended drawings, substantially identical components are given identical reference characters, and duplicate description thereof will be omitted or simplified.

In the present specification, the terms “above” and “under” are used not only as terms that indicate an upward direction (vertically above) and a downward direction (vertically under) in the absolute spatial recognition but also as terms that define relative positional relationships based on the order in which layers are stacked on top of each other in a layered structure. Moreover, the terms “above” and “under” are adopted not only in a case where two constituent elements in question are disposed with a space therebetween and another constituent element is interposed between these two constituent elements but also in a case where two constituent elements in question are disposed so as to be in contact with each other.

In the present specification and the drawings, the X axis, the Y axis, and the Z axis represent the three axes of a three-dimensional orthogonal coordinate system. The X axis and the Y axis are orthogonal to each other and are both orthogonal to the Z axis.

### Embodiment 1

A semiconductor laser element according to Embodiment 1 will be described.

### [Configuration of Semiconductor Laser Element]

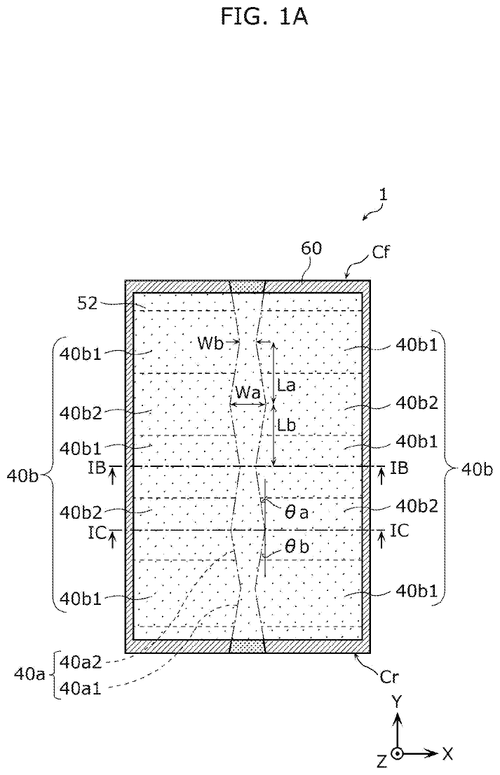

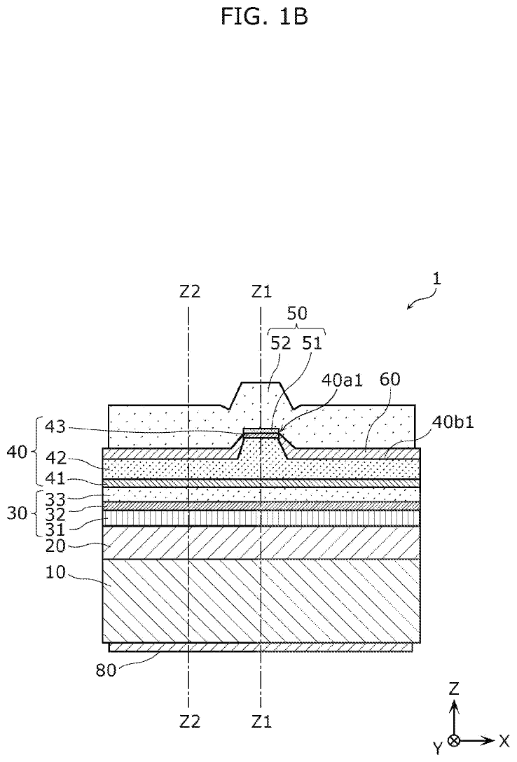

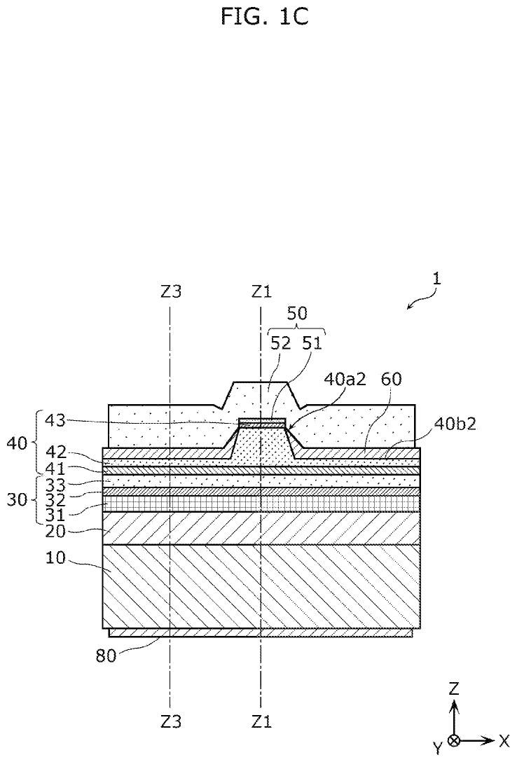

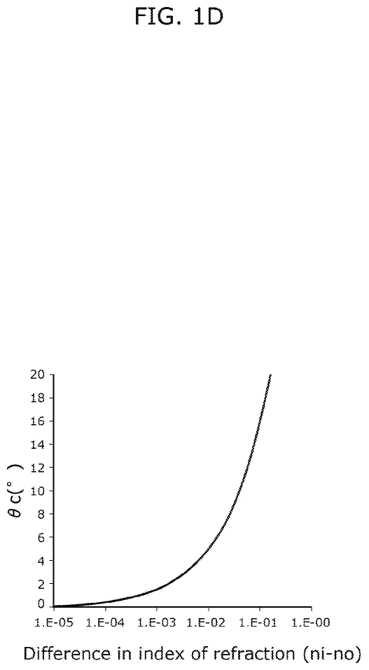

First, a configuration of a semiconductor laser element according to the present embodiment will be described with reference to FIG. 1A, FIG. 1B, and FIG. 1C. FIG. 1A is a schematic top view illustrating a configuration of semiconductor laser element 1 according to the present embodiment, and FIG. 1B and FIG. 1C are each a schematic sectional view illustrating a configuration of semiconductor laser element 1 according to the present embodiment. FIG. 1B shows a section of semiconductor laser element 1 taken along the IB-IB line indicated in FIG. 1A. FIG. 1C shows a section of semiconductor laser element 1 taken along the IC-IC line indicated in FIG. 1A.

Semiconductor laser element 1 according to the present embodiment is an element that emits laser light. As illustrated in FIG. 1B, semiconductor laser element 1 includes substrate 10, first semiconductor layer 20, light emitting layer 30, second semiconductor layer 40, and dielectric layer 60. According to the present embodiment, semiconductor laser element 1 further includes electrode member 50 and n-side electrode 80. Semiconductor laser element 1 includes a resonator that is formed by front-side end surface Cf and rear-side end surface Cr and emits laser light via front-side end surface Cf. Moreover, semiconductor laser element 1 includes a nitride semiconductor material.

Substrate 10 is, for example, a GaN substrate. According to the present embodiment, an n-type hexagonal GaN substrate whose principal plane is the (0001) plane is used as substrate 10. Substrate 10 may have any thickness that allows substrate 10 to be cleaved when semiconductor laser element 1 is singulated, and substrate 10 has a thickness of, for example, greater than or equal to 50 μm and less than or equal to 130 μm. According to the present embodiment, substrate 10 has a thickness of 90 μm.

First semiconductor layer 20 is a semiconductor layer of a first conductivity type and is disposed above substrate 10. According to the present embodiment, first semiconductor layer 20 includes a nitride semiconductor material. Specifically, first semiconductor layer 20 is an n-side clad layer composed of n-type Al_{0.03}Ga_{0.97}N and having a thickness of 3 μm. It is to be noted that the thickness and the Al composition of first semiconductor layer 20 are not limited to the example above. For example, first semiconductor layer 20 may have a thickness of greater than or equal to 0.5 μm and less than or equal to 5.0 μm, and the Al composition of first semiconductor layer 20 may be expressed by n-type AlₓGa₁₋ₓN (0<x<1). Moreover, first semiconductor layer 20 may include an n-type semiconductor layer other than n-type Al_{0.03}Ga_{0.97}N. Herein, in a case where at least one of the thickness or the Al composition of the n-side clad layer is too large, problems may arise, such as an occurrence of a crack caused by a difference between the lattice constant of the n-side clad layer and the lattice constant of the GaN substrate or an increase in the operation voltage caused by an increase in the series resistance.

Light emitting layer 30 is disposed above first semiconductor layer 20. According to the present embodiment, light emitting layer 30 includes a nitride semiconductor material. Specifically, light emitting layer 30 has a layered structure that includes n-side light guide layer 31 composed of n-type GaN and having a thickness of 0.2 μm, active layer 32 in which an In_{0.06}Ga_{0.94}N quantum well layer having a thickness of 5 nm is sandwiched by an In_{0.02}Ga_{0.98}N barrier layer having a thickness of 10 nm, and p-side light guide layer 33 composed of p-type GaN and having a thickness of 0.1 μm. According to the present embodiment, active layer 32 includes two quantum well layers, and each of the quantum well layers is sandwiched by a barrier layer. In this example, the number of quantum well layers is not limited to two, and one quantum well layer or three or more quantum well layers may be provided. Moreover, the In composition and the thickness of each quantum well layer and of each barrier layer are not limited to the above, and each quantum well layer and each barrier layer may have any composition and any thickness that allow light emitting layer 30 to emit light at greater than or equal to about 400 nm and less than or equal to about 470 nm.

Second semiconductor layer 40 is a semiconductor layer of a second conductivity type and is disposed above light emitting layer 30. Second semiconductor layer 40 includes waveguide 40a that guides laser light. In this example, the second conductivity type is a conductivity type that is different from the first conductivity type. According to the present embodiment, second semiconductor layer 40 includes a nitride semiconductor material. Specifically, second semiconductor layer 40 has a layered structure that includes electron barrier layer 41 composed of Al_{0.35}Ga_{0.65}N and having a thickness of 10 nm, p-side clad layer 42 constituted by a strained superlattice having a thickness of 0.66 μm and being formed by 220 repeated cycles of p-type Al_{0.06}Ga_{0.94}N having a thickness of 1.5 nm and p-type GaN having a thickness of 1.5 nm, and p-side contact layer 43 composed of p-type GaN and having a thickness of 0.05 μm. Herein, p-side contact layer 43 is formed as an uppermost layer of waveguide 40a. It is to be noted that the configuration of p-side clad layer 42 is not limited to the configuration indicated above. For example, A-side clad layer 42 may have a thickness of greater than or equal to 0.3 μm and less than or equal to 1 μm, and the composition of p-side clad layer 42 may be p-type AlₓGa₁₋ₓN (0<x<1).

Herein, p-side clad layer 42 includes a projection portion that extends in the direction of resonator length (i.e., in the direction of resonance of the laser light). The projection portion of this p-side clad layer 42 and p-side contact layer 43 constitute waveguide 40a of a stripe shape (in other words, of a ridge shape). Herein, p-side clad layer 42 further includes a planar surface portion served by planar portion 40b located at each side of waveguide 40a. In other words, the uppermost surface of each planar portion 40b is the surface of p-side clad layer 42, and p-side contact layer 43 is not formed on the uppermost surfaces of planar portions 40b.

As illustrated in FIG. 1A, the width of at least a portion of waveguide 40a is modulated with respect to the position in the direction of resonator length, which is the lengthwise direction of waveguide 40a, (i.e., in the direction of Y axis indicated in each drawing). Herein, the width of waveguide 40a is the dimension of waveguide 40a in the direction perpendicular to the direction of resonator length and perpendicular to the direction of the thickness of second semiconductor layer 40 (i.e., to the direction of Z axis indicated in each drawing). According to the present embodiment, waveguide 40a includes first waveguide 40a1 and second waveguide 40a2 that has a larger width than first waveguide 40a1 (i.e., has a larger dimension in the direction of X axis indicated in each drawing). First waveguide 40a1 and second waveguide 40a2 are disposed cyclically in an in an alternating manner in the direction of resonator length. Each position where first waveguide 40a1 and second waveguide 40a2 border each other may be set as appropriate. According to the present embodiment, such border positions are each set to a position where waveguide 40a has a width that is a mean width of waveguide 40a.

Meanwhile, the height of waveguide 40a from the uppermost surface of planar portion 40b (i.e., the dimension, in the direction of Z axis, of the projection portion of waveguide 40a projecting from planar portion 40b) varies depending on the position in the direction of resonator length. In other words, the thickness of the portion of second semiconductor layer 40 that lies outside waveguide 40a varies depending on the position in the direction of resonator length. According to the present embodiment, first waveguide 40a1 of waveguide 40a has a smaller height than second waveguide 40a2. In other words, the thickness of the portion of second semiconductor layer 40 that lies outside first waveguide 40a1 is greater than the thickness of the portion of second semiconductor layer 40 that lies outside second waveguide 40a2. According to the present embodiment, each planar portion 40b includes first planar portion 40b1 located at each side of first waveguide 40a1 of waveguide 40a, and second planar portion 40b2 located at each side of second waveguide 40a2 of waveguide 40a. The thickness of first planar portion 40b1 is greater than the thickness of second planar portion 40b2. Specifically, first waveguide 40a1 of waveguide 40a has a height of 600 nm, and second waveguide 40a2 has a height of 650 nm. With this configuration, the difference between the effective index of refraction inside waveguide 40a and the effective index of refraction outside waveguide 40a is greater at second waveguide 40a2 than at first waveguide 40a1. The detailed configuration of waveguide 40a will be described later.

Electrode member 50 is disposed above second semiconductor layer 40. Electrode member 50 is wider than waveguide 40a. In other words, the width of electrode member 50 (i.e., the width in the direction of X axis indicated in each drawing) is greater than the width of waveguide 40a (i.e., the width in the direction of X axis indicated in each drawing). Electrode member 50 is in contact with the upper surface of dielectric layer 60 and the upper surface of waveguide 40a.

According to the present embodiment, electrode member 50 includes p-side electrode 51 for supplying an electric current and pad electrode 52 disposed above p-side electrode 51.

Herein, p-side electrode 51 is in contact with the upper surface of waveguide 40a. Moreover, p-side electrode 51 is an ohmic electrode that is in an ohmic contact with p-side contact layer 43 at the upper side of waveguide 40a, and p-side electrode 51 is in contact with the upper surface of p-side contact layer 43 serving as the upper surface of waveguide 40a. For example, p-side electrode 51 is formed of a metal material, such as Pd, Pt, or Ni. According to the present embodiment, p-side electrode 51 has a two-layer structure consisting of Pd/Pt.

Pad electrode 52 is wider than waveguide 40a. Pad electrode 52 is in contact with dielectric layer 60. In other words, pad electrode 52 is formed so as to cover waveguide 40a and dielectric layer 60. Pad electrode 52 is formed, for example, of a metal material, such as Ti, Ni, Pt, or Au. According to the present embodiment, pad electrode 52 has a three-layer structure consisting of Ti/Pt/Au.

In this example, as illustrated in FIG. 1A, pad electrode 52 is formed so as to be contained within dielectric layer 60 as semiconductor laser element 1 is viewed from the above (i.e., contained within second semiconductor layer 40), in order to improve the yield rate when semiconductor laser element 1 is singulated. In other words, when semiconductor laser element 1 is viewed from the above, pad electrode 52 is not formed at the peripheral edge of semiconductor laser element 1. With this configuration, semiconductor laser element 1 can have a non-electric-current-injection region at its peripheral edge where no electric current is supplied.

Dielectric layer 60 is an insulating film formed on the side surfaces of waveguide 40a (i.e., on the surfaces intersecting with the direction of X axis), in order to trap the light within waveguide 40a. Dielectric layer 60 has an index of refraction lower than that of second semiconductor layer 40. Dielectric layers 60 is formed continuously from the side surfaces of waveguide 40a to extend above respective planar portions 40b. Dielectric layer 60 is disposed above second semiconductor layer 40. According to the present embodiment, dielectric layer 60 is formed around waveguide 40a so as to extend continuously above the side surfaces of p-side contact layer 43, the side surfaces of the projection portion of p-side clad layer 42, and the upper surface of p-side clad layer 42. According to the present embodiment, dielectric layer 60 is formed of SiO₂.

There is no particular limitation on the shape of dielectric layer 60, and dielectric layer 60 may be in contact with the side surfaces of waveguide 40a and with planar portions 40b. This configuration makes it possible to stably trap the light generated directly under waveguide 40a.

Moreover, in semiconductor laser element 1 aimed to operate at a high output power (i.e., a high output power operation), an end surface coating film of a dielectric multilayer film or the like is formed on front-side end surface Cf. It is difficult to form this end surface coating film only on the end surface, and the end surface coating film extends onto the upper surface of semiconductor laser element 1. In such a case, since pad electrode 52 is not formed at the end portions of semiconductor laser element 1 in the direction of resonator length (i.e., in the direction of Y axis indicated in each drawing), if the end surface coating film extends onto the upper surface of semiconductor laser element 1, the end surface coating film may make contact with dielectric layer 60 at one of the end portions of semiconductor laser element 1 in the direction of resonator length. In this case, if dielectric layer 60 is not formed, or if the film thickness of dielectric layer 60 is too small to trap the light, the light is affected by the end surface coating film, and this can cause the loss of light. Accordingly, in order to sufficiently trap the light generated in light emitting layer 30, the film thickness of dielectric layer 60 may be greater than or equal to 100 nm. Meanwhile, if the film thickness of dielectric layer 60 is too large, this makes it difficult to form pad electrode 52. Therefore, the film thickness of dielectric layer 60 may be less than or equal to the height of waveguide 40a.

Meanwhile, etching damage may remain in the side surfaces of waveguide 40a and in planar portions 40b in the etching process performed when waveguide 40a is formed, and a leakage electric current may be generated. Yet, an occurrence of an unnecessary leakage electric current can be reduced when waveguide 40a and planar portions 40b are covered by dielectric layer 60.

Herein, n-side electrode 80 is an electrode disposed under substrate 10 and is an ohmic electrode that makes an ohmic contact with substrate 10. For example, n-side electrode 80 is a layered film composed of Ti/Pt/Au. The configuration of n-side electrode 80 is not limited to this configuration. Herein, n-side electrode 80 may be a layered film in which Ti and Au are stacked on top of each other.

### [Detailed Configuration of Waveguide]

Next, a detailed configuration of waveguide 40a according to the present embodiment will be described.

As described above, second semiconductor layer 40 includes waveguide 40a constituted by the stripe-shaped projection portion that extends in the direction of resonator length (i.e., in the direction of Y axis indicated in each drawing) and planar portions 40b that each extend in the transverse direction from the root of waveguide 40a (i.e., in the direction of X axis indicated in each drawing).

The width of at least a portion of waveguide 40a is modulated with respect to the position within waveguide 40a in the direction of resonator length. In other words, the width of waveguide 40a varies with respect to the position in the direction of resonator length. According to the present embodiment, the width of waveguide 40a varies continuously, and first waveguide 40a1 that is a portion having a smaller width and second waveguide 40a2 having a greater width than first waveguide 40a1 are disposed in an alternating manner in the direction of Y axis. In this example, as illustrated in FIG. 1A, a local maximum value of the width of waveguide 40a is designated by Wa, and a local minimum value of the width is designated by Wb. Meanwhile, the shortest distance, in the direction of Y axis, from the position where the width of waveguide 40a is at a local maximum to the position where the width of waveguide 40a is at a local minimum and that is located on the side closer to the front side (located in the upper side in FIG. 1A) is defined as La, and the shortest distance, in the direction of Y axis, from the position where the width of waveguide 40a is at a local maximum to the position where the width of waveguide 40a is at a local minimum and that is located on the side closer to the rear side (located in the lower side of FIG. 1A) is defined as Lb. According to the present embodiment, the width of waveguide 40a changes linearly. An angle formed by the direction of resonator length and, of a side surface of waveguide 40a, the portion that extends toward the front side from the position where the width of waveguide 40a is at a local maximum is defined as θa, and an angle formed by the direction of resonator length and, of the side surface of waveguide 40a, the portion that extends toward the rear side from the position where the width of waveguide 40a is at a local maximum is defined as θb. Then, the following relationships hold.

θa=arctan{(Wa−Wb)/(2×La)} (Equation 1)

θb=arctan{(Wa−Wb)/(2×Lb)} (Equation 2)

The relationship in the magnitude between the values of θa and θb and the critical angle (defined as θc) described later determines whether the guided light is reflected or transmitted.

In other words, the guided light is totally reflected when the angle formed by a side surface of waveguide 40a that intersects with the widthwise direction of waveguide 40a (i.e., the direction of X axis) and the direction of resonator length is smaller than critical angle θc defined by the effective index of refraction inside waveguide 40a and the effective index of refraction outside waveguide 40a. Meanwhile, the guided light is transmitted when the angle formed by a side surface of waveguide 40a that intersects with the widthwise direction of waveguide 40a and the direction of resonator length is greater than critical angle θc. According to the present embodiment, critical angle θc is the maximum value of the angle (θa or θb) at which laser light is totally reflected by a side surface of waveguide 40a.

In one example, the width of waveguide 40a is greater than or equal to 1 μm and less than or equal to 100 μm. In order to operate semiconductor laser element 1 at a high optical output (e.g., at a certain watt level), local maximum value Wa of the width of waveguide 40a may be set to greater than or equal to 10 μm and less than or equal to 50 μm. As local minimum value Wb of the width of waveguide 40a is smaller, a higher order mode component can be reduced further. However, if local minimum value Wb is too small, the fundamental mode component (i.e., the fundamental transverse mode component) also experiences the loss and is reduced as a result. Meanwhile, if local minimum value Wb of the width of waveguide 40a is too large, the effect of reducing a higher order mode component is reduced. In order to efficiently suppress a higher order mode component while retaining the intensity of the fundamental mode, local minimum value Wb of the width of waveguide 40a may be set to greater than or equal to about one-quarter and less than or equal to about three-quarters of local maximum value Wa of the width.

Meanwhile, if distances La and Lb are set too small, θa and θb become too large, and thus the component that is transmitted increases. In contrast, if distances La and Lb are set too large, the number of portions in waveguide 40a where the width is small is reduced, and thus the effect of suppressing a higher order mode is reduced. According to the present embodiment, Wa is 16 μm, Wb is 10 μm, and La and Lb are each 30 μm. In this case, θa=θb=5.7° holds.

Alternatively, La and Lb may not be equal to each other. When La and Lb are not equal, the loss of a higher order mode may be varied between a first path and a returning path when the light reciprocates in the direction of Y axis within the resonator. For example, when La is greater than Lb, the loss of a higher order mode that is experienced when the light travels from the rear side to the front side can be increased. In addition, since the proportion of the portion where the width decreases from the rear side toward the front side within the resonator (i.e., the portion covered by distance La in FIG. 1A) increases, the loss of a higher order mode further increases.

Next, a method of obtaining critical angle θc will be described. According to the present embodiment, the structure of three-dimensional waveguide 40a (i.e., the ridge structure) is approximated by a two-dimensional slab waveguide structure with use of the equivalent index method, and the calculation is performed. First, the optical distribution and the effective index of refraction in the layering direction (i.e., an equivalent index of refraction) are calculated with use of the thickness and the index of refraction of each layer along the Z1-Z1 line indicated in FIG. 1B. Although details are omitted, the effective index of refraction is calculated by discretizing a two-dimensional scalar wave equation and by solving the eigenvalue problem. When the effective index of refraction along the Z1-Z1 line indicated in FIG. 1B is defined as ni, ni of 2.535 is obtained according to the present embodiment. In a similar manner, when the effective index of refraction along the Z2-Z2 line indicated in FIG. 1B is defined as no₁, no₁ of 2.527 is obtained. In a similar manner, when the effective index of refraction along the Z3-Z3 line indicated in FIG. 1C is defined as no₂, no₂ of 2.525 is obtained. Although these values are dependent on the thickness and the index of refraction of each semiconductor layer, in a case where second semiconductor layer 40 is a waveguide structure having a projection portion, like semiconductor laser element 1 according to the present embodiment, the relationships ni>no₁ and ni>no₂ are satisfied constantly.

In addition, as in the present embodiment, the effective index of refraction is smaller when the thickness of p-side clad layer 42 that lies outside waveguide 40a is smaller. Specifically, in the case of the present embodiment, the relationship no₁>no₂ is satisfied constantly.

Next, the maximum value of the angle held when the total reflection condition is satisfied is calculated with use of the Snell's law (this angle is defined as critical angle θc). The maximum value of this angle is defined as critical angle θc. Critical angle θc is defined by the effective index of refraction inside waveguide 40a and the effective index of refraction outside waveguide 40a. For example, when the critical angle in the structure illustrated in FIG. 1B is defined as θc1 and when the critical angle in the structure illustrated in FIG. 1C is defined as θc2, critical angles θc1 and θc2 are expressed as in the following equations based on the Snell's law.

θc1=90−arcsin(no₁/ni)

θc2=90−arcsin(no₂/ni)

According to the present embodiment, θc1 of 4.6° and θc2 of 5.1° are obtained.

Herein, since critical angle θc is dependent on the thickness and the index of refraction of each layer and the height of waveguide 40a, critical angle θc needs to be calculated for each structure for structures other than the structure according to the present embodiment. Herein, a relationship between critical angle θc and the difference between the effective indexes of refraction inside and outside waveguide 40a will be described with reference to FIG. 1D. FIG. 1D is a graph illustrating a result of calculating a relationship between critical angle θc and the difference (ni−no) between the effective indexes of refraction inside and outside waveguide 40a according to the present embodiment. In this example, the calculation is performed with ni fixed at 2.535 and with effective index of refraction no outside the waveguide varied. The calculation shows that critical angle θc is greater as the difference between the effective index of refraction inside waveguide 40a and the effective index of refraction outside waveguide 40a is greater.

As in the present embodiment, in a case where the height of the ridge (the thickness of p-side clad layer 42 that lies outside the ridge) varies depending on the position in the direction of resonator length, the critical angle varies at each position. For example, in a case where angle θa (=8b) determined by the shape of waveguide 40a as viewed from the above is 4.8°, θa>θc1 holds. Thus, the total reflection condition is not satisfied, and the light is transmitted in the structure portion illustrated in FIG. 1B. Meanwhile, since θa<θc2 holds, the total reflection condition is satisfied, and the light is totally reflected in the structure portion illustrated in FIG. 1C. In other words, the angle formed by a side surface of waveguide 40a that intersects with the widthwise direction of waveguide 40a and the direction of resonator length is greater than critical angle θc at first waveguide 40a1 and is smaller than critical angle θc at second waveguide 40a2. In this manner, when the height of the ridge is varied depending on the position in the direction of resonator length, waveguide 40a having a region where the total reflection condition is satisfied and a region where the total reflection condition is not satisfied can be achieved.

### [Method of Manufacturing Semiconductor Laser Element]

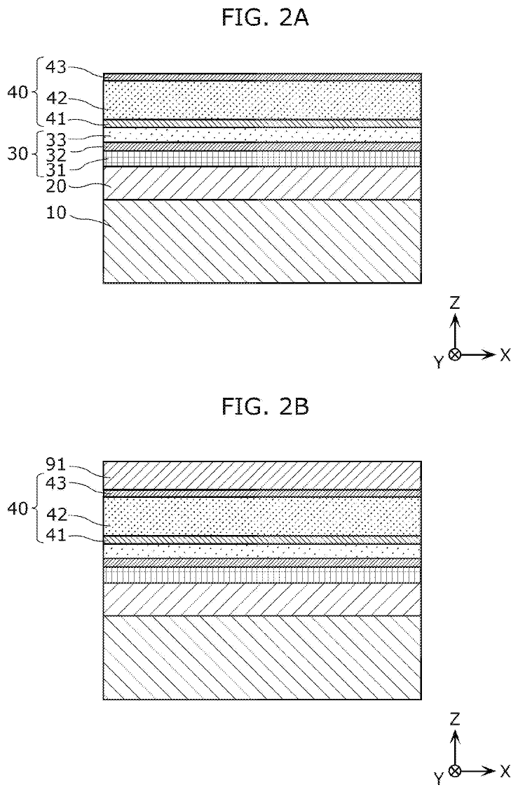

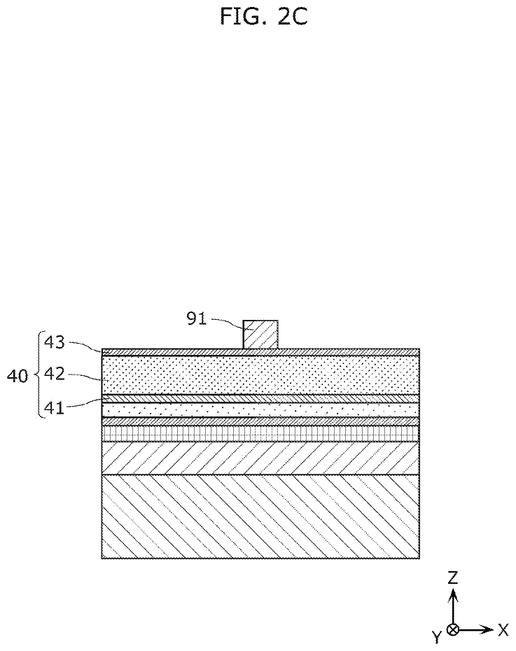

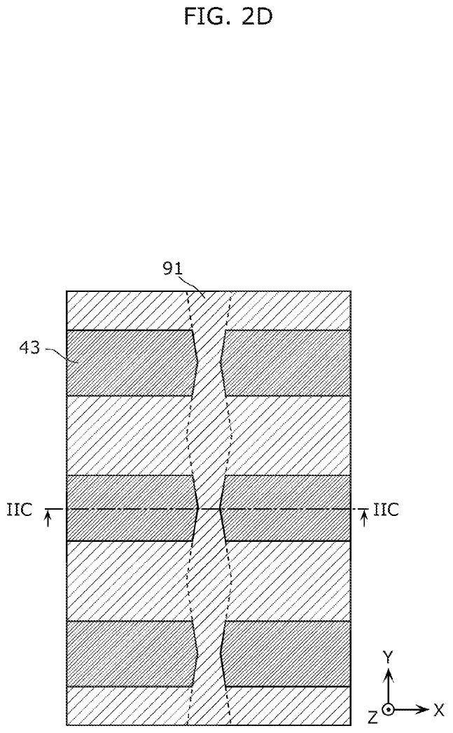

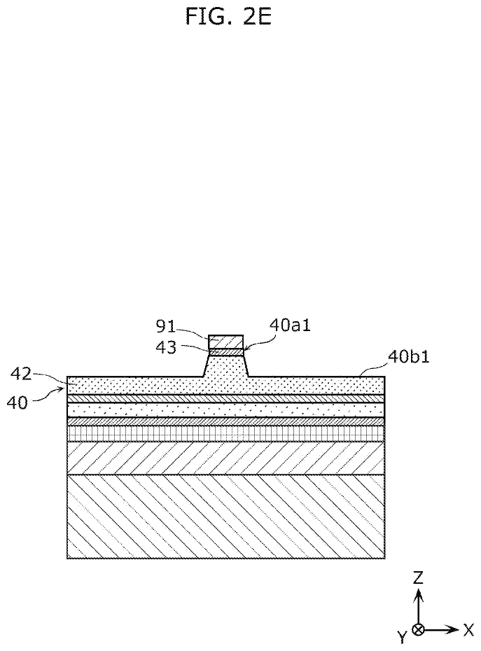

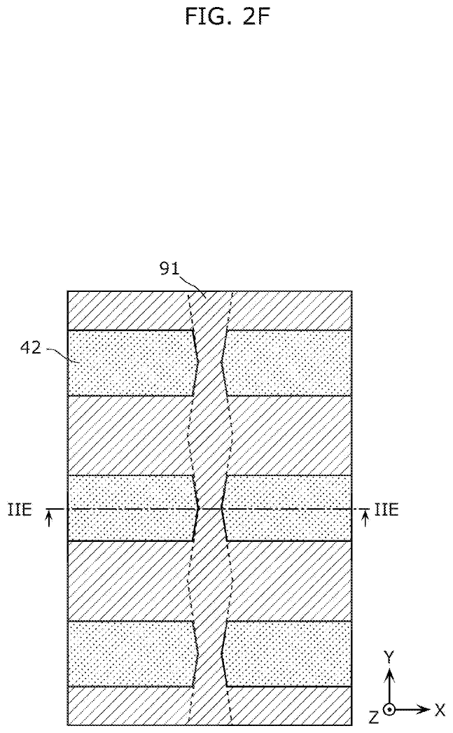

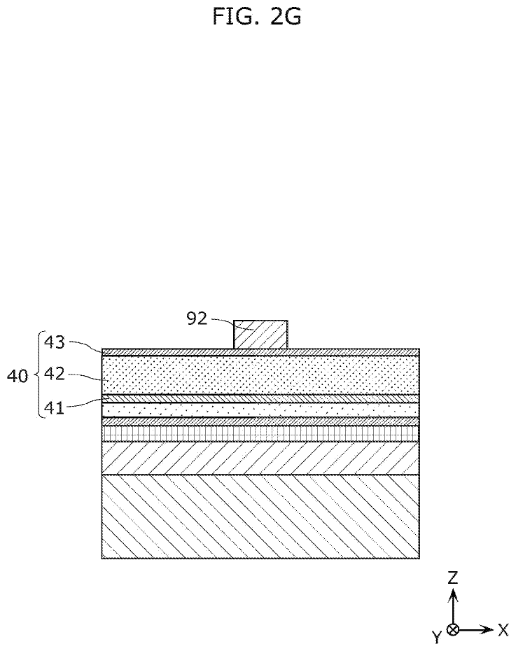

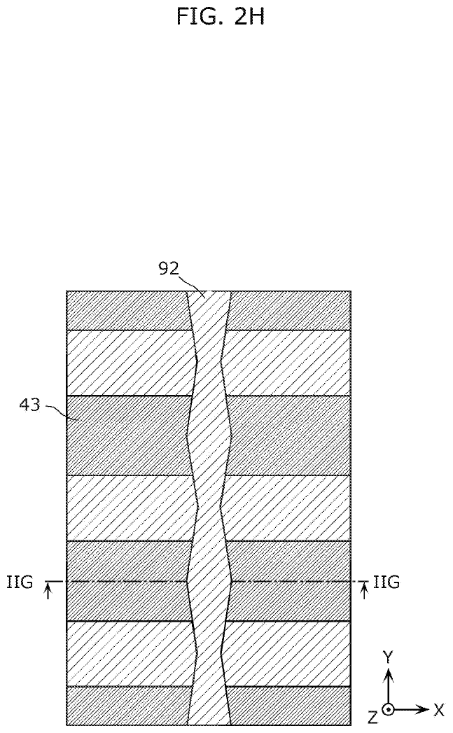

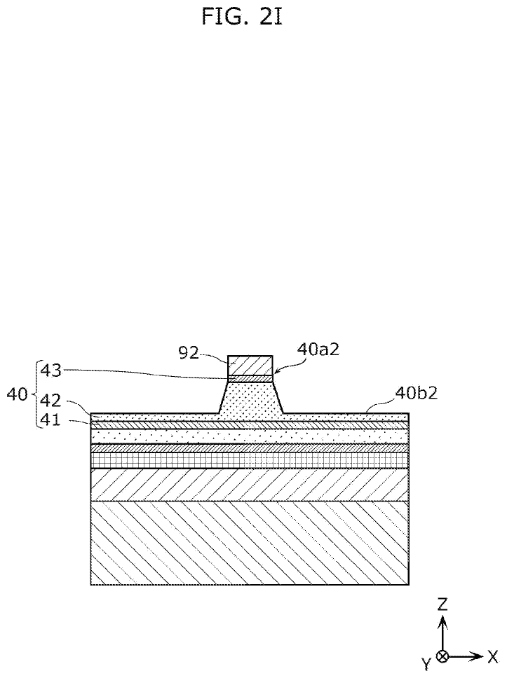

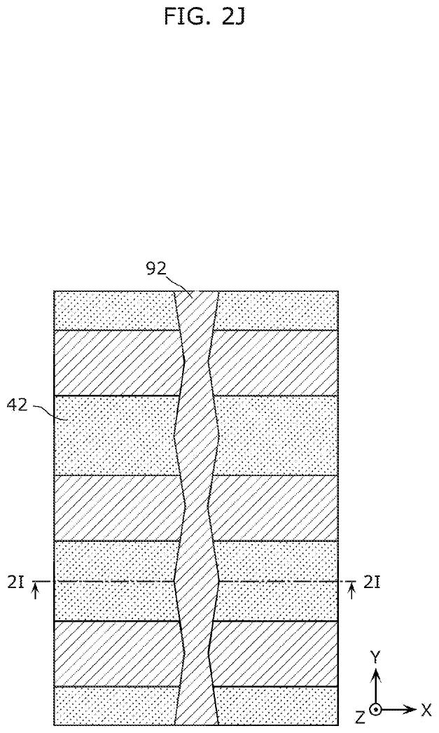

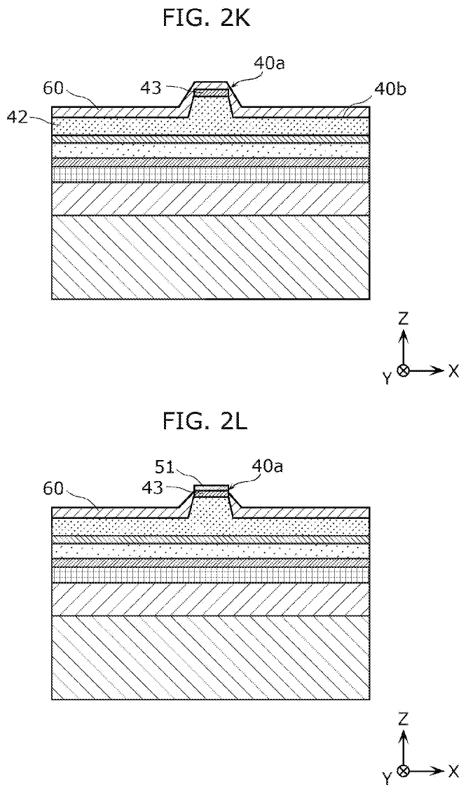

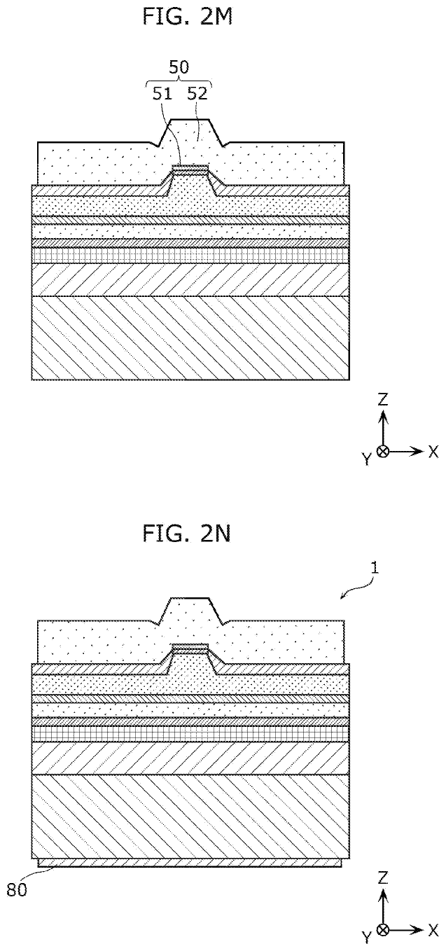

Next, a method of manufacturing semiconductor laser element 1 according to the present embodiment will be described with reference to FIG. 2A to FIG. 2N. FIG. 2A to FIG. 2C, FIG. 2E, FIG. 2G, FIG. 2I, and FIG. 2K to FIG. 2M are each a schematic sectional view illustrating a step of a method of manufacturing semiconductor laser element 1 according to the present embodiment. FIG. 2D, FIG. 2F, FIG. 2H, and FIG. 2J are each a schematic top view illustrating a step of the method of manufacturing semiconductor laser element 1 according to the present embodiment. FIG. 2C, FIG. 2E, FIG. 2G, and FIG. 2I show sections taken along, respectively, the IIC-IIC line indicated in FIG. 2D, the IIE-IIE line indicated in FIG. 2F, the IIG-IIG line indicated in FIG. 2H, and the 2I-2I line indicated in FIG. 2J.

First, as illustrated in FIG. 2A, with use of a metalorganic chemical vapor deposition (MOCVD) technique, first semiconductor layer 20, light emitting layer 30, and second semiconductor layer 40 are deposited sequentially on substrate 10 that is an n-type hexagonal GaN substrate whose principal plane is the (0001) plane. Specifically, as first semiconductor layer 20, an n-side clad layer composed of n-type AlGaN is deposited to a thickness of 3 μm on substrate 10 having a thickness of 400 μm. Then, n-side light guide layer 31 composed of n-type GaN is deposited to a thickness of 0.2 μm. Then, active layer 32 constituted by two cycles of a barrier layer composed of InGaN and an InGaN quantum well layer is deposited. Then, p-side light guide layer 33 composed of p-type GaN is deposited to a thickness of 0.1 μm. Then, electron barrier layer 41 composed of AlGaN is deposited to a thickness of 10 nm. Then, p-side clad layer 42 constituted by a strained superlattice having a thickness of 0.66 μm and formed by 220 repeated cycles of a p-type AlGaN layer having a film thickness of 1.5 nm and a GaN layer having a film thickness of 1.5 nm is deposited. Then, p-side contact layer 43 composed of p-type GaN is deposited to a thickness of 0.05 μm. In this example, in depositing each layer according to the present embodiment, trimethylgallium (TMG), trimethylaluminum (TMA), and trimethylindium (TMI), for example, are used as organic metal source materials containing, respectively, Ga, Al, and In. Meanwhile, ammonia (NH₃) is used as a nitrogen source material.

Next, as illustrated in FIG. 2B, first protection film 91 is deposited on p-side contact layer 43. Specifically, with use of a plasma chemical vapor deposition (CVD) technique in which silane (SiH₄) is used, a silicon oxide film (SiO₂) is deposited as first protection film 91 to a thickness of 300 nm. The deposition material for first protection film 91 is not limited to the aforementioned material, and, for example, any material, such as a dielectric body or a metal, that has selectivity with respect to etching of second semiconductor layer 40 described later can be used. Herein, the method of depositing first protection film 91 is not limited to the plasma CVD technique, and, for example, any known deposition method, such as a thermal CVD technique, a sputtering technique, a vacuum vapor deposition technique, or a pulsed laser deposition technique, can be used.

Next, as illustrated in FIG. 2C and FIG. 2D, patterning is performed such that first protection film 91 of a predetermined shape remains. Specifically, a protection film composed of photoresist is deposited on first protection film 91, first protection film 91 is selectively removed with use of a photolithography technique and an etching technique such that first protection film 91 of a predetermined shape remains, and then the protection film composed of photoresist is removed. The predetermined shape is the shape of waveguide 40a and second planar portions 40b2 illustrated in FIG. 1A as they are viewed from the above. In other words, the predetermined shape is the shape excluding the region of first planar portions 40b1 as second semiconductor layer 40 is viewed from the above.

Examples of lithography techniques that can be used include a photolithography technique in which a short wavelength light source is used, an electron beam lithography technique of directly drawing with an electron beam, or a nanoimprint technique. Examples of etching techniques that can be used include dry etching through reactive ion etching (RIE) in which a fluorine-based gas, such as CF₄, is used, or wet etching in which hydrofluoric acid (HF) or the like diluted to about 1:10 is used. Examples of solvents that can be used to remove the protection film include an organic solvent, such as acetone.

Next, as illustrated in FIG. 2E and FIG. 2F, with first protection film 91 serving as a mask, p-side contact layer 43 and p-side clad layer 42 are etched, and thus first waveguides 40a1 and first planar portions 40b1 are formed in second semiconductor layer 40. Specifically, first waveguides 40a1 are formed under first protection film 91 located at the center in the horizontal direction illustrated in FIG. 2E. In addition, p-side contact layer 43 and p-side clad layer 42 that are located in the region in which first protection film 91 is not formed are etched, and thus first planar portions 40b1 are formed. In etching p-side contact layer 43 and p-side clad layer 42, dry etching through an RIE technique in which a chlorine-based gas, such as Cl₂, is used may be used.

Then, first protection film 91 is removed. Examples of methods that can be used to remove first protection film 91 include dry etching through reactive ion etching (RIE) in which a fluorine-based gas, such as CF₄, is used, or wet etching in which hydrofluoric acid (HF) or the like diluted to about 1:10 is used.

Next, as illustrated in FIG. 2G and FIG. 2H, second protection film 92 of a predetermined shape is formed on second semiconductor layer 40. Specifically, a silicon oxide film (SiO₂) is deposited as second protection film 92 to a thickness of 300 nm. Then, second protection film 92 is removed selectively with use of a photolithography technique and an etching technique such that second protection film 92 of a predetermined shape remains. The predetermined shape is the shape of waveguide 40a and first planar portions 40b1 illustrated in FIG. 1A as they are viewed from the above. In other words, the predetermined shape is the shape excluding the region of second planar portions 40b2 as second semiconductor layer 40 is viewed from the above.

Next, as illustrated in FIG. 2I and FIG. 2J, with second protection film 92 serving as a mask, p-side contact layer 43 and p-side clad layer 42 are etched, and thus second waveguides 40a2 and second planar portions 40b2 are formed in second semiconductor layer 40.

Next, as illustrated in FIG. 2K, second protection film 92 of the predetermined shape is removed through wet etching with use of hydrofluoric acid, and then dielectric layer 60 is deposited so as to cover p-side contact layer 43 and p-side clad layer 42. In other words, dielectric layer 60 is formed on waveguide 40a and planar portions 40b. As dielectric layer 60, for example, a silicon oxide film (SiO₂) is deposited to a thickness of 300 nm through a plasma CVD technique with use of silane (SiH₄).

Next, as illustrated in FIG. 2L, only dielectric layer 60 that lies on waveguide 40a is removed through a photolithography technique and wet etching in which hydrofluoric acid is used, and thus the upper surface of p-side contact layer 43 is exposed. Thereafter, p-side electrode 51 composed of Pd/Pt is formed only on waveguide 40a with use of a vacuum vapor deposition technique and a lift-off technique. Specifically, p-side electrode 51 is formed on p-side contact layer 43 exposed through dielectric layer 60. Herein, the method of depositing p-side electrode 51 is not limited to a vacuum vapor deposition technique, and a sputtering technique, a pulsed laser deposition technique, or the like may be used. Moreover, the material for forming p-side electrode 51 may be any material, such as a Ni/Au-based material or a Pt-based material, that makes an ohmic contact with second semiconductor layer 40 (p-side contact layer 43).

Next, as illustrated in FIG. 2M, pad electrode 52 is formed so as to cover p-side electrode 51 and dielectric layer 60. Specifically, negative resist is patterned through a photolithography technique or the like onto a portion other than a portion where pad electrode 52 is to be formed, and pad electrode 52 composed of Ti/Pt/Au is formed on the entire surface above substrate 10 through a vacuum vapor deposition technique or the like. Then, the electrode in an unnecessary portion is removed through a lift-off technique. With this process, pad electrode 52 of a predetermined shape can be formed on p-side electrode 51 and dielectric layer 60. In this manner, electrode member 50 constituted by p-side electrode 51 and pad electrode 52 is formed.

Next, as illustrated in FIG. 2N, n-side electrode 80 is formed on a lower surface of substrate 10 (i.e., on the principal surface that is opposite to the principal surface on which first semiconductor layer 20 and so on are disposed). Specifically, n-side electrode 80 composed of Ti/Pt/Au is formed on the lower surface of substrate 10 through a vacuum vapor deposition technique or the like, and this n-side electrode 80 is patterned with use of a photolithography technique and an etching technique. Thus, n-side electrode 80 of a predetermined shape is formed.

In this manner, semiconductor laser element 1 according to the present embodiment can be manufactured.

### [Mode of Mounting Semiconductor Laser Element]

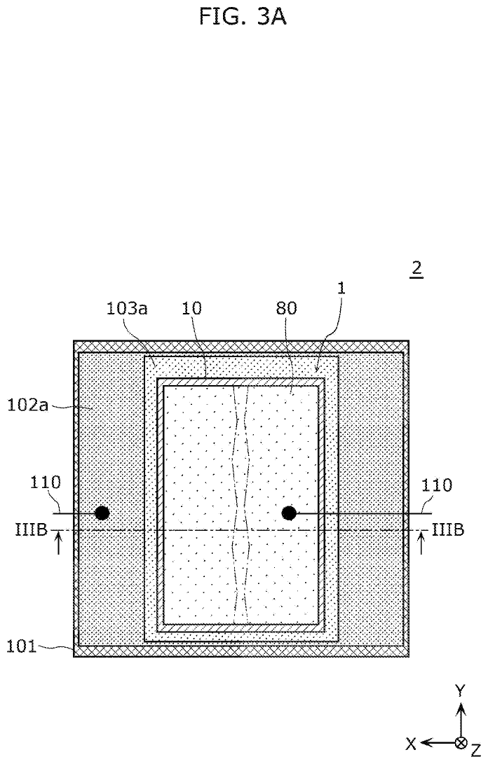

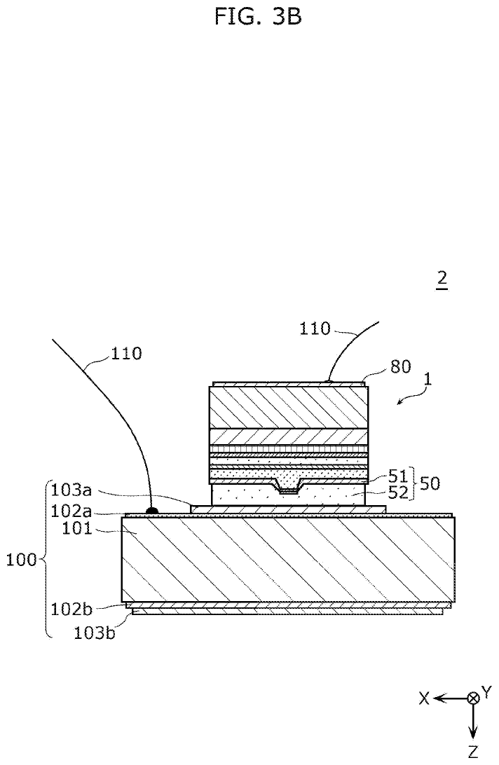

Next, with reference to FIG. 3A and FIG. 3B, a mode of mounting semiconductor laser element 1 according to Embodiment 1 will be described. FIG. 3A and FIG. 3B are, respectively, a schematic top view and a schematic sectional view of semiconductor laser device 2 provided with semiconductor laser element 1 according to the present embodiment. FIG. 3B shows a section of semiconductor laser device 2 taken along the IIIB-IIIB line indicated in FIG. 3A.

As illustrated in FIG. 3B, semiconductor laser device 2 according to the present embodiment includes semiconductor laser element 1 and submount 100.

As illustrated in FIG. 3B, submount 100 includes pedestal 101, first electrode 102a, second electrode 102b, first bonding layer 103a, and second bonding layer 103b.

Pedestal 101 is a pedestal disposed under substrate 10 of semiconductor laser element 1 and functions as a heat sink. There is no particular limitation on the material for pedestal 101, and pedestal 101 may be formed of a material having a thermal conductivity that is equivalent to or higher than or equal to the thermal conductivity of semiconductor laser element 1. Examples of such materials include ceramics, such as aluminum nitride (AlN) or silicon carbide (SiC); an elemental metal, such as diamond (C), Cu, or Al, deposited through CVD; or an alloy, such as CuW.

As illustrated in FIG. 3A and FIG. 3B, first electrode 102a is disposed on one of the surfaces of pedestal 101. Meanwhile, second electrode 102b is disposed on the other surface of pedestal 101. First electrode 102a and second electrode 102b are each, for example, a layered film constituted by three metal films: a Ti film having a film thickness of 0.1 μm, a Pt film having a film thickness of 0.2 μm, and a Au film having a film thickness of 0.2 μm.

First bonding layer 103a is disposed on first electrode 102a. Second bonding layer 103b is disposed on second electrode 102b. First bonding layer 103a and second bonding layer 103b are, for example, eutectic solder composed of a gold-tin alloy that contains 70% Au and 30% Sn in terms of their content by percentage.

Semiconductor laser element 1 is mounted on submount 100. The mode of mounting according to the present embodiment is such that the p-side of semiconductor laser element 1 (i.e., the side where electrode member 50 is located) is connected to submount 100. In other words, a junction-down mounting is employed. Therefore, pad electrode 52 of semiconductor laser element 1 is connected to first bonding layer 103a of submount 100.

Herein, in a case where semiconductor laser element 1 is mounted with gold-tin solder used for first bonding layer 103a, as in the present embodiment, the gold-tin solder undergoes an eutectic reaction with the gold in pad electrode 52 or the gold in first electrode 102a. This may make it difficult to identify the border. If that is the case, the thickness of first bonding layer 103a is defined as the distance from the layer (e.g., Pt) that does not undergo an eutectic reaction with the gold-tin solder of pad electrode 52 to the layer (e.g., Pt) that does not undergo an eutectic reaction with the gold-tin solder of first electrode 102a.

Meanwhile, wire 110 is connected to pad electrode 52 of semiconductor laser element 1 and to first electrode 102a of submount 100 through wire bonding. This configuration makes it possible to supply an electric current to semiconductor laser element 1 via wire 110.

Herein, although the illustration is omitted, submount 100 is mounted, for example, to a metal package, such as a CAN package, for the purpose of improving heat dissipation performance and simplifying the handling. In other words, submount 100 is bonded to the metal package by second bonding layer 103b. Herein, pedestal 101 itself may function as a package. In this case, submount 100 does not have to include second bonding layer 103b.

### [Workings and Advantageous Effects of Semiconductor Laser Element]

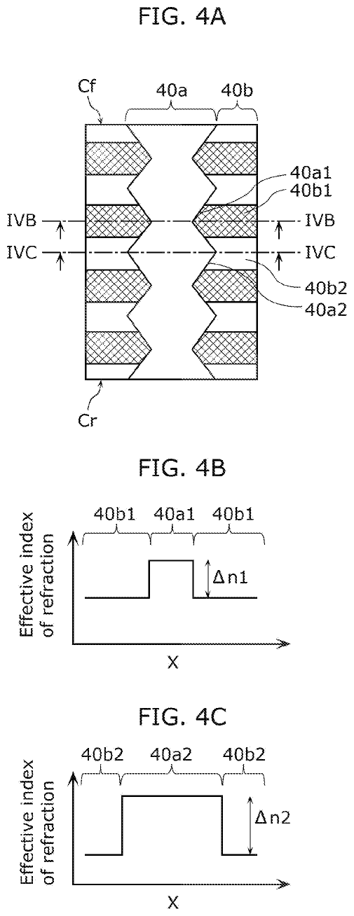

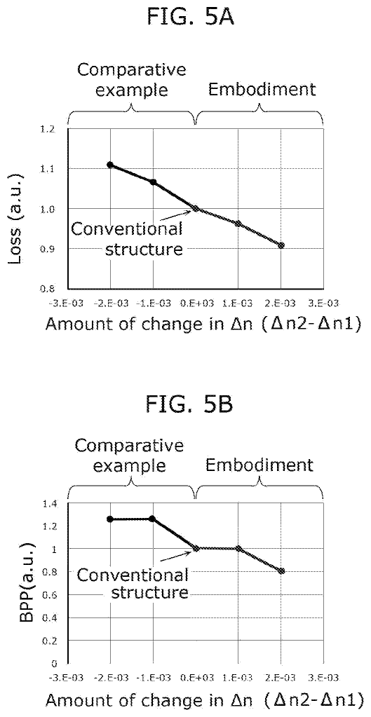

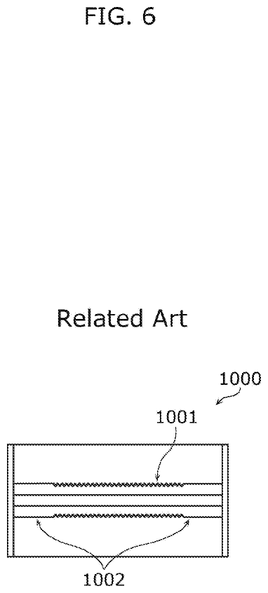

Next, some workings and advantageous effects of semiconductor laser element 1 according to the present embodiment will be described with reference to FIG. 4A to FIG. 4C, FIG. 5A, and FIG. 5B.

FIG. 4A is a top view illustrating, in a simplified manner, a configuration of semiconductor laser element 1 according to the present embodiment. FIG. 4B is a diagram illustrating a distribution of effective indexes of refraction in semiconductor laser element 1 observed along the IVC-IVC section indicated in FIG. 4A, and FIG. 4C is a diagram illustrating a distribution of effective indexes of refraction in semiconductor laser element 1 observed along the IVC-IVC section indicated in FIG. 4A.

In waveguide 40a illustrated in FIG. 4A, there are two types of differences between the effective indexes of refraction inside and outside the ridge. As illustrated in FIG. 4B, the difference between the effective index of refraction of first waveguide 40a1 and the effective index of refraction of first planar portion 40b1 is designated by Δnt. Meanwhile, as illustrated in FIG. 4C, the difference between the effective index of refraction of second waveguide 40a2 and the effective index of refraction of second planar portion 40b2 is designated by Δnt.

With reference to FIG. 5A, described is a result of calculating the loss of light of the fundamental mode observed when the amount of change in Δn (i.e., Δn2−Δn1) that is the amount of change in the aforementioned two differences between the effective indexes of refraction with respect to the position in the direction of resonator length. FIG. 5A is a graph illustrating a result of calculating a relationship between the amount of change in Δn and the loss of light of the fundamental mode. It can be seen that, when the amount of change in Δn (Δn2−Δn1) is positive (the right half of the graph shown in FIG. 5A) as in the present embodiment, that is, when difference Δn between the effective indexes of refraction is smaller in the portion where the width of waveguide 40a is small, the loss of the light of the fundamental mode is smaller than that in the conventional structure. The conventional structure as used herein is a structure in which Δnt=Δn2 holds, that is, a structure in which difference Δn between the effective indexes of refraction is constant along the direction of resonator length. In contrast, when the amount of change in Δn (Δn2−Δn1) calculated according to a comparative example is negative (the left half of the graph shown in FIG. 5A), that is, when difference Δn between the effective indexes of refraction is greater in the portion where the width of waveguide 40a is small, the loss is greater than that in the conventional structure.

In semiconductor laser element 1 according to the present embodiment illustrated in FIG. 4A, laser light is propagated within waveguide 40a in the direction of Y axis during the laser oscillation. At this time, the laser light experiences the loss at a portion where the width of waveguide 40a is small (i.e., at first waveguide 40a1). Of the laser light, mainly a higher order mode experiences the loss, but the fundamental mode experiences the loss as well. Therefore, reducing difference Δn between the effective indexes of refraction at a portion where the width of waveguide 40a is small makes it possible to reduce the loss of the fundamental mode.

Next, a beam parameter product (BPP) serving as an index of beam quality will be described with reference to FIG. 5B. FIG. 5B is a graph illustrating a result of calculating a relationship between the amount of change in Δn and a BPP. As can be seen from FIG. 5B, the BPP is smaller than that in the conventional structure when Δnt−Δn1>0 holds at which the loss of the fundamental mode is small. This is because the ratio of the fundamental mode having a higher beam quality becomes relatively higher as the loss of the fundamental mode decreases.

### [Recapitulation]

As described above, in semiconductor laser element 1 according to the present embodiment, the difference between the effective index of refraction inside waveguide 40a and the effective index of refraction outside waveguide 40a is greater at second waveguide 40a2 than at first waveguide 40a1. With this configuration, the loss of the fundamental mode of the laser light can be reduced in first waveguide 40a1 where waveguide 40a has a small width. Along with this effect, the proportion of the fundamental mode having a higher beam quality in the laser light that semiconductor laser element 1 emits can be increased, and thus semiconductor laser element 1 of a high beam quality can be achieved.

Moreover, in semiconductor laser element 1, the angle formed by a side surface of waveguide 40a that intersects with the widthwise direction of waveguide 40a and the direction of resonator length may be greater than the critical angle at first waveguide 40a1 and may be smaller than the critical angle at second waveguide 40a2. This configuration makes it possible to keep the fundamental mode from being reflected in first waveguide 40a1. Accordingly, semiconductor laser element 1 of a high beam quality can be achieved.

Moreover, in semiconductor laser element 1, the thickness of the portion of second semiconductor layer 40 that lies outside first waveguide 40a1 may be greater than the thickness of the portion of second semiconductor layer 40 that lies outside second waveguide 40a2. With this configuration, difference Δnt between the effective index of refraction of first waveguide 40a1 and the effective index of refraction of first planar portion 40b1 can be made smaller than difference Δnt between the effective index of refraction of second waveguide 40a2 and the effective index of refraction of second planar portion 40b2.

Moreover, in semiconductor laser element 1, dielectric layer 60 may have a smaller index of refraction than second semiconductor layer 40. This configuration makes it possible to trap the laser light in second semiconductor layer 40.

### [Variations and Others]

Thus far, semiconductor laser element 1 according to the present disclosure has been described based on the embodiments, but the present disclosure is not limited to the embodiments described above.

For example, semiconductor laser element 1 according to the foregoing embodiments is a nitride semiconductor laser element, but the configuration of the semiconductor laser element is not limited to this configuration. For example, a semiconductor laser element may be a semiconductor laser element formed of a semiconductor other than a nitride semiconductor and may be, for example, a semiconductor laser element formed of a gallium arsenide-based semiconductor material.

Moreover, p-side clad layer 42 according to the foregoing embodiments includes two planar portions each having a different thickness. Alternatively, the p-side clad layer may have three or more planar portions each having a different thickness. The thickness of each planar portion may vary continuously with respect to the position in the direction of resonator length.

Moreover, the difference between the effective index of refraction of waveguide 40a and the effective index of refraction of the portion outside waveguide 40a is modulated by modulating the thickness of planar portion 40b, according to the foregoing embodiments. Alternatively, the difference between the effective indexes of refraction may be modulated through other techniques. For example, the index of refraction of the portion of the first semiconductor layer that lies outside the waveguide may be modulated. Specifically, a layer having an index of refraction lower than that of the waveguide may be disposed outside the second waveguide.

Moreover, the width of waveguide 40a is varied linearly in accordance with the position in the direction of resonator length, according to the foregoing embodiments. Alternatively, such a width may be varied curvilinearly. Moreover, the waveguide may include a portion where the width does not change regardless of the position in the direction of resonator length.

Moreover, waveguide 40a according to the foregoing embodiments is formed by a ridge structure. Alternatively, waveguide 40a may be formed by a structure other than a ridge structure. For example, the waveguide may be formed by an embedded heterostructure.

Moreover, an embodiment obtained by making various modifications that a person skilled in the art can conceive of to the foregoing embodiments and an embodiment achieved by combining, as desired, the constituent elements and the functions of the foregoing embodiments within the scope that does not depart from the spirit of the present disclosure are also encompassed by the present disclosure.

### INDUSTRIAL APPLICABILITY

The semiconductor laser element according to the present disclosure can be used as a light source of, for example but not limited to, an image display apparatus, lighting equipment, or industrial equipment, and is effective in particular as a light source of equipment that requires a relatively high optical output.

1. A semiconductor laser element that emits laser light, the semiconductor laser element comprising:
a substrate;
a first semiconductor layer above the substrate;
a light emitting layer above the first semiconductor layer;
a second semiconductor layer above the light emitting layer; and
a dielectric layer above the second semiconductor layer, wherein
the second semiconductor layer includes a waveguide that guides the laser light,
a width of at least a portion of the waveguide is modulated with respect to a position in a direction of resonator length, the direction being a longitudinal direction of the waveguide,
the waveguide includes a first waveguide and a second waveguide that is wider than the first waveguide, and
a difference between an effective index of refraction inside the waveguide and an effective index of refraction outside the waveguide is greater at the second waveguide than at the first waveguide.

2. The semiconductor laser element according to claim 1, wherein
an angle formed by a side surface intersecting with a widthwise direction of the waveguide and the direction of resonator length is greater than a critical angle at the first waveguide and smaller than the critical angle at the second waveguide, the critical angle being defined by the effective index of refraction inside the waveguide and the effective index of refraction outside the waveguide.

3. The semiconductor laser element according to claim 1, wherein
the second semiconductor layer is thicker outside the first waveguide than outside the second waveguide.

4. The semiconductor laser element according to claim 1, wherein
the dielectric layer has a smaller index of refraction than the second semiconductor layer.
